(19) United States
(12) Patent Application Publication
(10) Pub. No.: US 2025/0316599 A1
(43) Pub. Date: Oct. 9, 2025

(54) PACKAGE STRUCTURE AND MANUFACTURING METHOD THEREOF

(71) Applicant: Taiwan Semiconductor Manufacturing Company, Ltd., Hsinchu (TW)

(72) Inventors: Hsuan-Ting Kuo, Taichung City (TW); Hsiu-Jen Lin, Hsinchu County (TW); Cheng-Yu Kuo, Kaohsiung City (TW); Po-Ching Wu, Hsinchu (TW); An-Jhih Su, Taoyuan City (TW)

(73) Assignee: Taiwan Semiconductor Manufacturing Company, Ltd., Hsinchu (TW)

(21) Appl. No.: 18/629,939

(22) Filed: Apr. 9, 2024

(51) Int. Cl. H01L 23/538; G02B 6/124; G02B 6/13; H01L 21/48; H01L 23/00; H01L 23/15; H01L 25/16

(52) U.S. Cl. CPC H01L 23/5384; G02B 6/124; G02B 6/13; H01L 21/4857; H01L 21/486; H01L 23/15; H01L 23/5383; H01L 23/5389; H01L 25/167; H01L 24/16; H01L 2224/16225

(57) ABSTRACT

A package structure and a manufacturing method thereof are provided. The package includes a glass substrate, a through-substrate-via and a redistribution structure. The glass substrate includes a first optical waveguide. The through-substrate-via penetrates through the glass substrate. The redistribution structure is disposed on the glass substrate and electrically connected to the through-substrate-via.

### BACKGROUND

Recently the demand for large-sized circuit substrate is increased to package various devices for multi-functions and applications. Due to the increasing of the circuit substrate size, the electrical paths for signal transmission may be longer and affecting the transmission efficiency.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic sectional view illustrating an exemplary package structure in accordance with some embodiments of the present disclosure.

FIG. 2 is a schematic sectional view illustrating an exemplary package structure in accordance with some embodiments of the present disclosure.

FIG. 3 is a schematic sectional view illustrating an exemplary package structure in accordance with some embodiments of the present disclosure.

FIG. 4A through FIG. 4P are schematic sectional views at various stages in a method of fabricating a package structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated.

According to embodiments of the present disclosure, a package structure is described. The package structure includes a glass substrate including an optical waveguide, a redistribution structure and a through-substrate-via. Since the glass substrate has good mechanical properties, compatible coefficient of thermal expansion (CTE) and tunable optical properties, the glass substrate can be used as the core substrate of the package structure and is suitable for large area application, and thereby the warpage may be minimized, and a portion of the glass substrate may be used as the optical waveguide to transmit optical signal to increase transmission bandwidth.

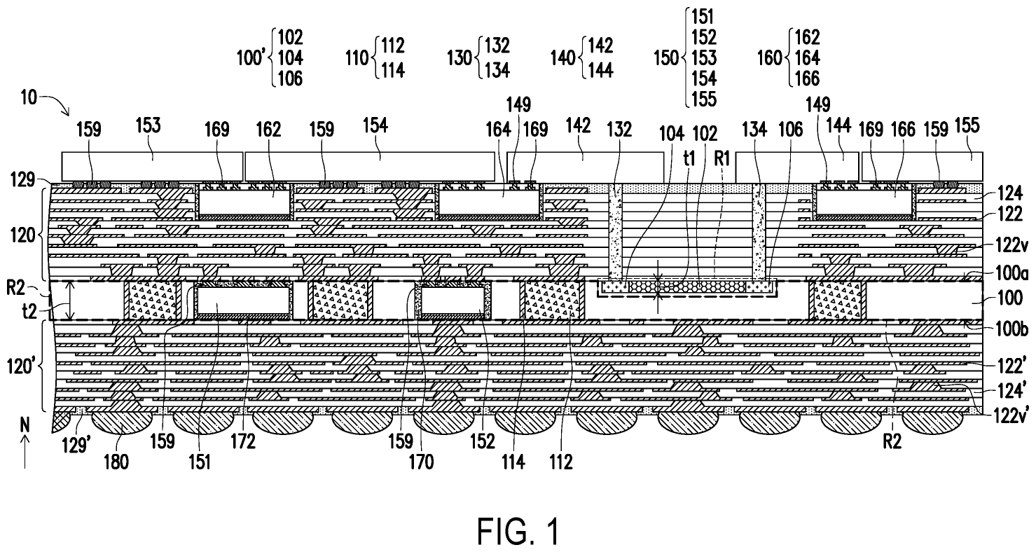

FIG. 1 is a schematic sectional view illustrating an exemplary package structure 10 in accordance with some embodiments of the present disclosure.

Referring to FIG. 1, the package structure 10 includes a glass substrate 100, a through-substrate-via 110 and a redistribution structure 120. The glass substrate 100 includes a first region R1 and a second region R2. A refraction index of the first region R1 is larger than a refraction index of the second region R2. The through-substrate-via 110 penetrates through the glass substrate 100 in the second region R2. The redistribution structure 120 disposed on the glass substrate 100 and electrically connected to the through-substrate-via 110.

The first region R1 includes and serves as an optical waveguide 102. The optical waveguide 102 may be located close to a surface of the glass substrate 100. For example, in FIG. 1, the glass substrate 100 has a first surface 100a and a second surface 100b opposite to the first surface 100a. The optical waveguide 102 is located close to the first surface 100a of the glass substrate 100. However, this is not limited. The optical waveguide 102 may be located close to the second surface 100b of the glass substrate 100 in other embodiments. This shows that the optical waveguide 102 is embedded in and integrated with the surface of the glass substrate 100. That is, the optical waveguide 102 may be regarded as a glass waveguide.

In some embodiments, the glass substrate 100 may be a silicate glass such as soda-lime glass, borosilicate glass, phosphosilicate glass or the like. In some embodiments, the optical waveguide 102 (or the first region R1 of the glass substrate 100) includes ions selected from a group of Li⁺, Na⁺, K⁺, Rb⁺, Cs⁺, Ag⁺ and Tl⁺ to increase the refraction index of the glass substrate 100 in the first region R1, so that the refraction index of the optical waveguide 102 (i.e. the refraction index of the first region R1 of the glass substrate 100) is greater than the refraction index of the glass substrate 100 in the second region R2. In this way, the light can be transmitted through total internal reflection within the optical waveguide 102. The wavelength of light transmitted by the optical waveguide 102 may be determined by adjusting the type of ions or the ion concentration of the ions in the optical waveguide 102. In some embodiments, the optical waveguide 102 is configured to guide infrared light, such as light with wavelengths in the range of about 850 nm to about 1550 nm.

In some embodiments, an ion concentration of the ions in the optical waveguide 102 is larger than an ion concentration of the ions in the second region R2 of the glass substrate 100. In some embodiments, the second region R2 of the glass substrate 100 is substantially free of the ions selected from the group of Li⁺, Na⁺, K⁺, Rb⁺, Cs⁺, Ag⁺ and Tl⁺. In some embodiments, the ion concentration of the ions in the optical waveguide 102 gradually decreases away from the first surface 100a of the glass substrate 100.

A thickness t1 of the optical waveguide 102 (also referred to the thickness of the first region R1) is smaller than a thickness t2 of the glass substrate 100. In some embodiments, the thickness t1 of the optical waveguide 102 is between about 2 μm to about 20 μm. Within this range, the optical signal may be effectively transmitted within the optical waveguide 102 and the signal integrity may be improved. In some embodiments, the thickness t2 of the glass substrate 100 is about 300 μm to about 1500 μm.

In some embodiments, the first region R1 further includes grating couplers 104 and 106 optically coupled with the optical waveguide 102. The grating couplers 104 and 106 are configured to direct light to a certain direction. For example, the grating couplers 104 and 106 may turn the transmission direction of light about 90 degrees, but it is not limited thereto. In some embodiments, the optical waveguide 102 is located between the grating couplers 104 and 106. The grating couplers 104 and 106 and the optical waveguide 102 may be collectively referred to a photonic component 100′ integrated in the glass substrate 100.

FIG. 1 schematically illustrates one photonic component 100′ in the glass substrate 100, but this is no limited thereto. The amount, arrangement and/or configuration of the photonic component may be adjusted based on the demand and design requirements. Also, the amount, arrangement and/or configuration of the through-substrate-via 110 is not limited to the drawings of the embodiments, and may be selected and designated based on the demand and design requirements.

In some embodiments, the through-substrate-via 110 includes an insulating pillar 112 and a conductive layer 114. The insulating pillar 112 may be embedded in the glass substrate 100, and the conductive layer 114 may surrounds the insulating pillar 112. The insulating pillar 112 may be spaced apart from the glass substrate 100 by the conductive layer 114. In other words, the conductive layer 114 may be located between the insulating pillar 112 and the glass substrate 100. In some embodiments, the conductive layer 114 is in direct contact with the glass substrate 100 and the insulating pillar 112.

In some embodiments, a material of the insulating pillar 112 includes an ajinomoto buildup film (ABF), epoxy resin or other suitable insulating resin. In some embodiments, a material of the conductive layer 114 includes metal or metal alloys, for example, tungsten (W), cobalt (Co), copper (Cu), aluminum (Al), nickel (Ni), ruthenium (Ru), gold (Au), silver (Ag), molybdenum (Mo), manganese (Mg), zirconium (Zr), alloys of the aforementioned metal, a combination thereof, or other suitable materials, which is not limited.

In some embodiments, the through-substrate-via 110 further includes a magnetic layer (not shown) surrounding the insulating pillar 112 and disposed between the conductive layer 114 and the glass substrate 100, which may improve the power efficiency. In an embodiment where the through-substrate-via includes the magnetic layer, the magnetic layer is in direct contact with the glass substrate 100. In some embodiments, a material of the magnetic layer includes iron (Fe), cobalt (Co), nickel (Ni), iron oxides, nickel oxides, copper oxides, magnesium oxide (MgO), manganese bismuthide (MnBi), manganese antimonide (MnSb), iron yttrium oxide (Y₃Fe₅O₁₂), chromium oxide (CrO₂), manganese arsenide (MnAs), or cadmium zinc telluride (CdZnTe), a combination thereof or other suitable ferromagnetic materials.

The package structure 10 further includes a first optical conductive via 132 and a second optical conductive via 134 penetrating through the redistribution structure 120 to optically connect with the first region R1. The first optical conductive via 132 and the second optical conductive via 134 may be collectively referred to an optical conductive via 130. In some embodiments, the first optical conductive via 132 may be optically connected with the optical waveguide 102 through the grating coupler 104, and the second optical conductive via 134 may be optically connected with the optical waveguide 102 through the grating coupler 106. In other words, the grating coupler 104 is optically coupled between the waveguide 102 and the first optical conductive via 132 to change the transmission direction of light between the waveguide 102 and the first optical conductive via 132. Similarly, the grating coupler 106 is optically coupled between the waveguide 102 and the second optical conductive via 134 to change the transmission direction of light between the waveguide 102 and the second optical conductive via 134.

The package structure 10 further includes a first photonic chip 142 and a second photonic chip 144 disposed on the redistribution structure 120. In some embodiments, the top surfaces of the first photonic chip 142 and the second photonic chip 144 face away from the redistribution structure 120, and the bottom surfaces of the first photonic chip 142 and the second photonic chip 144 face the redistribution structure 120. The first photonic chip 142 may be optically connected to the first region R1 through the first optical conductive via 132, and the second photonic chip 144 may be optically connected to the first region R1 through the second optical conductive via 132. The first optical conductive via 132, the second optical conductive via 134 and the first region R1 of the glass substrate 100 form an optical path to transfer an optical signal between the first photonic chip 142 and the second photonic chip 144. The first photonic chip 142 and the second photonic chip 144 may be collectively referred to a photonic chip 140. In some embodiments, the first region R1 of the glass substrate 100 is overlapped with the first photonic chip 142 and the second photonic chip 144 in a normal direction N the glass substrate 100 to communicate between the first photonic chip 142 and the second photonic chip 144.

In some embodiments, the first photonic chip 142 and the second photonic chip 144 each includes an electronic die (not shown) and a photonic die (not shown) bonded to each other. In some embodiments, the electronic die may be electrically connected with the photonic die and the photonic die may face the redistribution structure 120 and be optically connected to the optical waveguide 102 through the optical conductive via 130 (such as the first optical conductive via 132 or the second optical conductive via 134). In some embodiments, the electronic die is an electronic integrated circuit (EIC) and the photonic die is a photonic integrated circuit (PIC), such that the electrical signals may be converted to the photonic signals in the photonic chip 140, or vice versa. Since the photonic signals have the characteristics of high bandwidth and low power consumption, it is suitable for long-range signal transmission to improve the transmission efficiency and power efficiency of the package structure 10.

In some embodiments, the electronic die of the photonic chip 140 may be electrically connected with the bridge chip 160 and/or the redistribution structure 120. For example, the first photonic chip 142 and the second photonic chip 144 may include conductive connectors 149 disposed on their bottom surfaces to be physically and electrically connected to the bridge chip 160 (such as bridge chip 164 or bridge chip 166). The conductive connectors 149 may include micro-bumps, metal pillars, controlled collapse chip connection (C4) bumps, a ball grid array (BGA) bumps or balls, solder balls, or the like.

In some embodiments, the photonic die of the photonic chip 140 may include waveguides (not shown) corresponding to the optical conductive via 130 (such as the first optical conductive via 132 or the second optical conductive via 134) to optically connect the photonic chip 140 and the optical conductive via 130 in the redistribution structure 120. The refraction indexes of the waveguides in the photonic chip 140 may be substantially identical to the refraction index of the corresponding optical conductive via 130 in the redistribution structure 120.

In some embodiments, the first photonic chip 142 is in direct contact with the first optical conductive via 132, and the second photonic chip 144 is in direct contact with the second optical conductive via 132. For example, the first optical conductive via 132 may be in direct contact with a waveguide disposed in the first photonic chip 142, and the second optical conductive via 132 may be in direct contact with a waveguide disposed in the second photonic chip 144. That is, there is no gap between the photonic chip 140 and the optical conductive via 130, such that the signal loss caused by light transmitting outside the optical path may be reduced.

In some embodiments, the first optical conductive via 132 and the second optical conductive via 134 each includes a light-transmitting material which is able to transmit infrared light. For example, the first optical conductive via 132 and the second optical conductive via 134 may each includes a polymer material and nano-fillers distributed in the polymer material. The polymer material may include poly(methylmethacrylate) (PMMA), polycarbonate (PC), a combination thereof or other suitable polymer material. The nano-fillers may include silicon oxide, aluminum oxide, titanium oxide or other suitable nano-fillers. The nano-fillers may be added into the polymer material to adjust the refraction index of the optical conductive via 130. In some embodiments, a refraction index of the first optical conductive via 132, a refraction index of the second optical conductive via 134 and the refraction index of the first region R1 of the glass substrate 100 (specifically, the refraction index of the optical waveguide 102 and/or the refraction index of the grating couplers 104 and 106) are substantially identical to reduce the signal loss caused by light transmitting outside the optical path.

In some embodiments, the redistribution structures 120 includes a plurality of redistribution layers 122 and a plurality of dielectric layers 124 stacked alternatively on the first surface 100a of the glass substrate 100, and a plurality of conductive vias 122v between the adjacent redistribution layers 122 to physically and electrically connect the adjacent redistribution layers 122. The first optical conductive via 132 and the second optical conductive via 134 may penetrate through the stacked dielectric layers 124 and may be spaced apart from the redistribution layers 122 by the dielectric layers. That is, the first optical conductive via 132 and the second optical conductive via 134 are laterally encapsulated by the dielectric layers 124.

In some embodiments, the package structure 10 further includes a redistribution structure 120′ disposed on the second surface 100b of the glass substrate 100. Similar to the redistribution structure 120, the redistribution structure 120′ may include a plurality of redistribution layers 122′ and a plurality of dielectric layers 124′ stacked alternatively on the second surface 100b of the glass substrate 100, and a plurality of conductive vias 122v′ between the adjacent redistribution layers 122′ to physically and electrically connect the adjacent redistribution layers 122′. In some embodiments, the through-substrate-via 110 is electrically connected between the redistribution structure 120 and the redistribution structure 120′, such that the redistribution layers 122 and 122′ on the opposite side of the glass substrate 100 can be electrically connected.

In some embodiments, the package structure 10 further includes a passivation layer 129 disposed on the redistribution structure 120 and a passivation layer 129′ disposed on the redistribution structure 120′. In some embodiments, the first optical conductive via 132 and the second optical conductive via 134 further extend through the passivation layer 129. In some embodiments, the package structure 10 further includes a plurality of conductive terminals 180 disposed on the passivation layer 129′ and electrically connected with the redistribution structure 120′. The conductive terminals 180 may include micro-bumps, metal pillars, controlled collapse chip connection (C4) bumps, a ball grid array (BGA) bumps or balls, solder balls, or the like.

The package structure 10 further includes a plurality of chips 150 (such as chips 151 to 155) disposed on the redistribution structure 120 or in the glass substrate 100. The plurality of chips 150 may be electronic chip, such as application-specific integrated circuit (ASIC) chips, analog chips (for example, wireless and radio frequency chips), digital chips (for example, a baseband chip), integrated passive devices (IPDs), voltage regulator chips, sensor chips, memory chips, or the like.

In FIG. 1, the chips 151 and 152 are embedded in the glass substrate 100 in the second region R2 and electrically connected with the redistribution structure 120. In some embodiments, the top surfaces of the chips 151 and 152 are close to the first surface 100a of the glass substrate 100, and the bottom surfaces of the chips 151 and 152 are close to the second surface 100b of the glass substrate 100. The chips 151 and 152 each includes conductive connectors 159 disposed on their top surfaces to be physically and electrically connected to the bottommost redistribution layer 122 of the redistribution structure 120. In some embodiments, a surface of the optical waveguide 102 substantially levels with a surface of the chip 151 and/or the chip 152. For example, the top surface of the conductive connectors 159 of the chip 151 or the chip 152 substantially levels with a top surface of the optical waveguide 102 (i.e. the first surface 100a of the glass substrate 100). On the other hand, the chips 153 to 155 are disposed on the passivation layer 129 and electrically connected with the redistribution structure 120. In some embodiments, the top surfaces of the chips 153 to 155 faces away from the redistribution structure 120, and the bottom surfaces of the chips 153 to 155 faces the redistribution structure 120. The chips 153 to 155 each includes conductive connectors 159 disposed on their bottom surfaces and extending through the passivation layer 129 to be physically and electrically connected to the topmost redistribution layer 122 of the redistribution structure 120. In some embodiments, the conductive connectors 159 may include micro-bumps, metal pillars, controlled collapse chip connection (C4) bumps, a ball grid array (BGA) bumps or balls, solder balls, or the like. In some embodiments, an underfill (not shown) is optionally disposed between the gap of the chips 153-155 and the passivation layer 129 to at least laterally cover the conductive connectors 159 to enhance the bonding between the chips 153-155 and the redistribution structure 120 and/or the bridge chip 160.

In some embodiments, the package structure 10 further includes a bridge chip 160 (such as a bridge chip 162, a bridge chip 164 or a bridge chip 166) disposed in the redistribution structure 120 and electrically connected between the chips 150 or between the chip 150 and the photonic chip 140 to shorten the electrical signal transmission path between devices. In some embodiments, the top surface of the bridge chip 160 faces the chips 153-155 or the photonic chip 140, and the bottom surface of the bridge chip 160 faces away from the chips 153-155 or the photonic chip 140. In some embodiments, each bridge chip 160 includes conductive connectors 169 disposed on its top surface to electrically connect the bridge chip 160 to the external devices. For example, the bridge chip 162 is electrically connected between the chips 153 and 154. The bridge chip 164 is electrically connected between the chip 154 and the first photonic chip 142. The bridge chip 166 is electrically connected between the chip 155 and the second photonic chip 144. However, the disclosure is not limited thereto. In other embodiments, the package structure 10 may not include any bridge chips, the chips 153-155 and/or the photonic chip 140 may be electrically connected to each other simply by the redistribution structure 120.

In some embodiments, the bridge chips 160 is embedded in the dielectric layers 124 of the redistribution structure 120. In some embodiments, the bridge chip 160 includes a semiconductor chip which provides local silicon interconnect. In some embodiments, the bridge chip 160 includes capacitors (not shown) formed in the semiconductor substrate to improve the power efficiency between the devices. In some embodiments, the conductive connectors 169 may include micro-bumps, metal pillars, controlled collapse chip connection (C4) bumps, a ball grid array (BGA) bumps or balls, solder balls, or the like.

In some embodiments, an insulating filling material 170 is laterally connected between the chips 151 or 152 and the glass substrate 100 or between the bridge chips 160 and the dielectric layers 124. The insulating filling material 170 may include epoxy resin, phenol resin or other suitable insulating material. In some embodiments, the insulating filling material 170 may further include fillers (such as silica or the like) to optimize the thermal expansion coefficient of the insulating filling material 170. In some embodiments, the bottom surface of the bridge chip 160 is attached to the redistribution structure 120 by an adhesive layer 172. The adhesive layer 172 may be die attach film, epoxy resin or other suitable adhesive material. In some embodiments, the adhesive layer 172 is also disposed between the bottom surfaces of the chips 151 or 152 and the redistribution structure 120′.

The amount, arrangement and/or configuration of the photonic chips 140, the chips 150, bridge chips 160 are not limited to the drawings of the embodiments, and may be selected and designated based on the demand and design requirements.

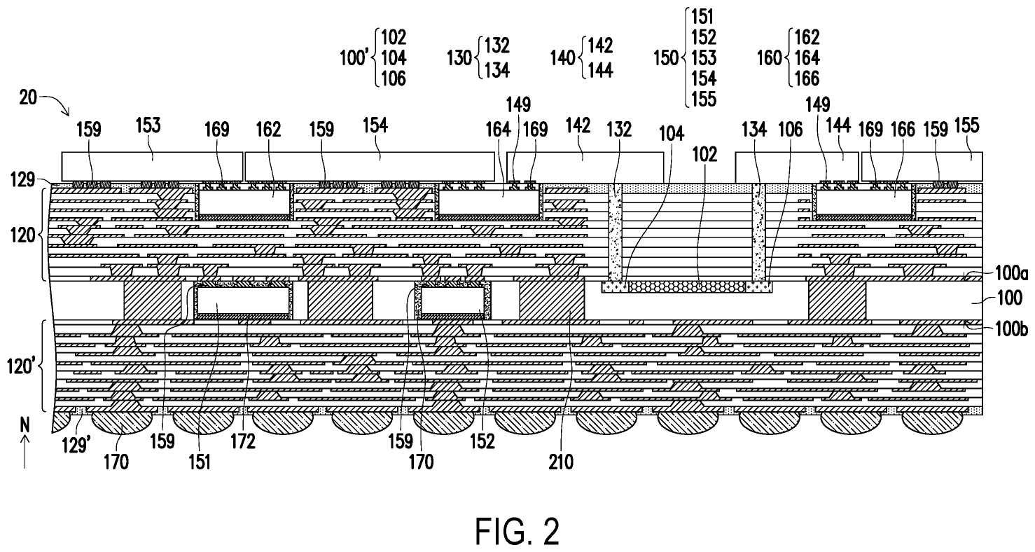

FIG. 2 is a schematic sectional view illustrating an exemplary package structure 20 in accordance with some embodiments of the present disclosure. It should be noted herein that, in embodiment provided in FIG. 2, element numerals and partial content of the embodiments provided in FIG. 1 are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 2, the difference between the present embodiment to the embodiment of FIG. 1 is that the package structure 20 includes a glass substrate 100, a through-substrate-via 210 and a redistribution structure 120. The through-substrate-via 210 penetrates through the glass substrate 100 in the second region R2 to electrically connect between the redistribution structure 120 and the redistribution structure 120′. The through-substrate-via 210 includes a conductive pillar in contact with the glass substrate 100. In other words, the through-substrate-via 210 is a conductive solid pillar and does not include an insulating pillar. In some embodiments, a material of the conductive pillar includes metal or metal alloys, for example, tungsten (W), cobalt (Co), copper (Cu), aluminum (Al), nickel (Ni), ruthenium (Ru), gold (Au), silver (Ag), molybdenum (Mo), manganese (Mg), zirconium (Zr), alloys of the aforementioned metal, a combination thereof, or other suitable materials.

In some embodiments, the through-substrate-via 210 further includes a magnetic layer (not shown) surrounding the conductive pillar to improve the power efficiency. In an embodiment where the through-substrate-via 210 includes the magnetic layer, the magnetic layer is in direct contact with the glass substrate 100 and the conductive pillar. The number of the through-substrate-via 210 is not limited to the drawings of the embodiments, and may be selected and designated based on the demand and design requirements.

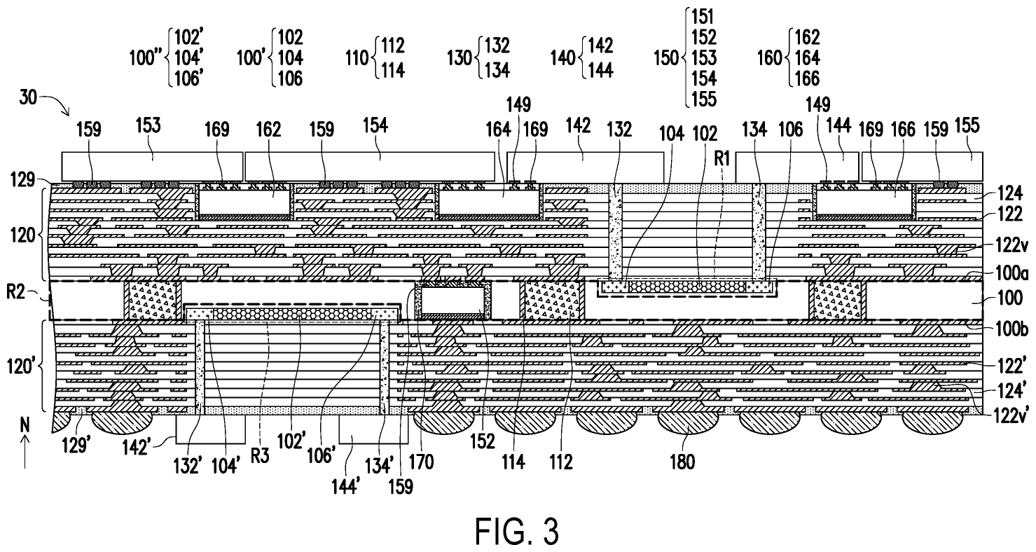

FIG. 3 is a schematic sectional view illustrating an exemplary package structure 30 in accordance with some embodiments of the present disclosure. It should be noted herein that, in embodiment provided in FIG. 3, element numerals and partial content of the embodiments provided in FIG. 1 are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 3, the difference between the present embodiment to the embodiment of FIG. 1 is that the glass substrate 100 of the package structure 30 further includes a third region R3. A refraction index of the third region R3 is greater than the refraction index of the second region R2. The third region 3 is different form the second region R2. The refraction index of the third region R3 may be greater than, equal to, or less than the refraction index of the first region R1. In some embodiments, the third region 3 of the glass substrate 100 includes ions selected from a group of Li⁺, Na⁺, K⁺, Rb⁺, Cs⁺, Ag⁺ and Tl⁺ to increase the refraction index of the glass substrate 100 in the third region 3, so that the refraction index of the third region R3 is greater than the refraction index of the glass substrate 100 in the second region R2. In some embodiments, an ion concentration of the ions in the third region 3 is larger than an ion concentration of the ions in the second region R2 of the glass substrate 100. In some embodiments, the ion concentration of the ions in the third region 3 gradually decreases away from the second surface 100b of the glass substrate 100.

In some embodiments, the third region R3 includes a photonic component 100″ containing a second optical waveguide 102′ and grating couplers 104′ and 106′ optically coupled with the second optical waveguide 102′. In some embodiments, the photonic component 100″ is located close to the second surface 100b of the glass substrate 100, but the disclosure is not limited thereto. The photonic component 100″ may be located close to the first surface 100a of the glass substrate 100. The materials and/or the configuration of the second optical waveguide 102′ and grating couplers 104′ and 106′ may be similar to the materials and/or the configuration of the first optical waveguide 102 and the grating couplers 104 and 106. Here, the first optical waveguide 102 may refer to the aforementioned optical waveguide 102 in the first region R1.

In some embodiments, the second optical waveguide 102′ is not overlapped with the first optical waveguide 102 in the normal direction N of the glass substrate 100, but it is not limited thereto. In other embodiments, the second optical waveguide 102′ is overlapped with the first optical waveguide 102 in the normal direction N of the glass substrate 100.

The package structure 30 further includes a third optical conductive via 132′, a fourth optical conductive via 134′, a third photonic chip 142′ and a fourth photonic chip 144′. The third optical conductive via 132′ and the fourth optical conductive via 134′ penetrate through the redistribution structure 120′ and the passivation layer 129′ to be optically connected with the photonic component 100″. The third photonic chip 142′ is disposed on the passivation layer 129′ and is optically connected to the second optical waveguide 102′ through the third optical conductive via 132′ and the grating coupler 104′. The fourth photonic chip 144′ is disposed on the passivation layer 129′ and is optically connected to the second optical waveguide 102′ through the fourth optical conductive via 134′ and the grating coupler 106′. The materials and/or the configuration of the third optical conductive via 132′ and the fourth optical conductive via 134′ may be similar to the materials and/or the configuration of the first optical conductive via 132 and the second optical conductive via 134. The materials and/or the configuration of the third photonic chip 142′ and the fourth photonic chip 144′ may be similar to the materials and/or the configuration of the first photonic chip 142 and the second photonic chip 144.

The third optical conductive via 132′, the fourth optical conductive via 134′ and the third region R3 of the glass substrate 100 form an optical path to transfer an optical signal between the third photonic chip 142′ and the fourth photonic chip 144′. In some embodiments, a refraction index of the third optical conductive via 132′, a refraction index of the fourth optical conductive via 134′ and the refraction index of the third region R3 of the glass substrate 100 (specifically, the refraction index of the second optical waveguide 102′ and/or the refraction index of the grating couplers 104′ and 106′) are substantially identical to reduce the signal loss caused by light transmitting outside the optical path.

In some embodiments, the third photonic chip 142′ is in direct contact with the third optical conductive via 132′, and the fourth photonic chip 144′ is in direct contact with the fourth optical conductive via 132′. For example, the third optical conductive via 132′ may be in direct contact with a waveguide disposed in the third photonic chip 142′, and the fourth optical conductive via 132′ may be in direct contact with a waveguide disposed in the fourth photonic chip 144′. That is, there is no gap between the third photonic chip 142′ and the third optical conductive via 132′ as well as between the fourth photonic chip 144′ and the fourth optical conductive via 134′, such that the signal loss caused by light transmitting outside the optical path may be reduced. In some embodiments, the refraction indexes of the waveguides in the third photonic chip 142′ and the fourth photonic chip 144′ may be substantially identical to the refraction indexes of the third optical conductive via 132′ and the fourth optical conductive via 134 in the redistribution structure 120′.

In some embodiments, additional chips (not shown) may be disposed on the passivation layer 129′ and electrically connected with the redistribution structure 120′. In some embodiments, additional bridge chips (not shown) may be disposed in the redistribution structure 120′ and electrically connected between the additional chips and the third photonic chip 142′ or the fourth photonic chip 144′.

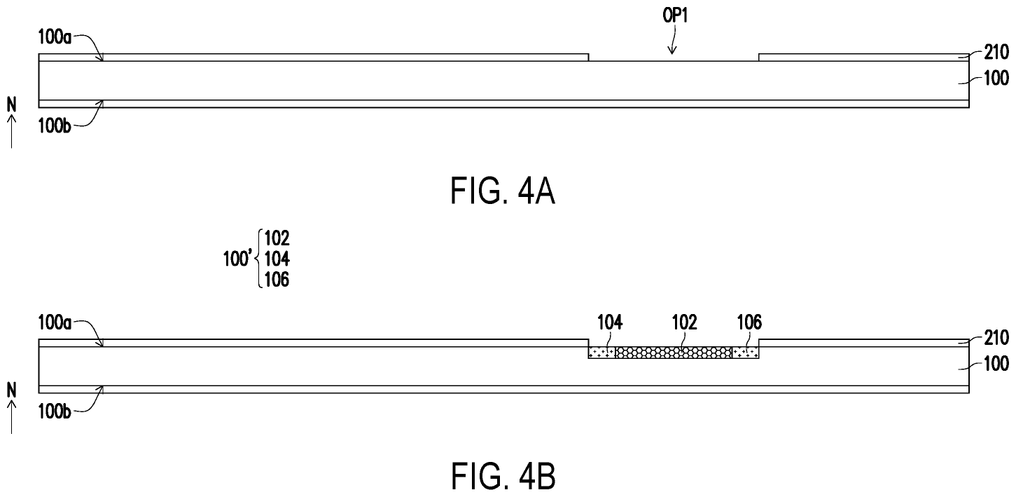

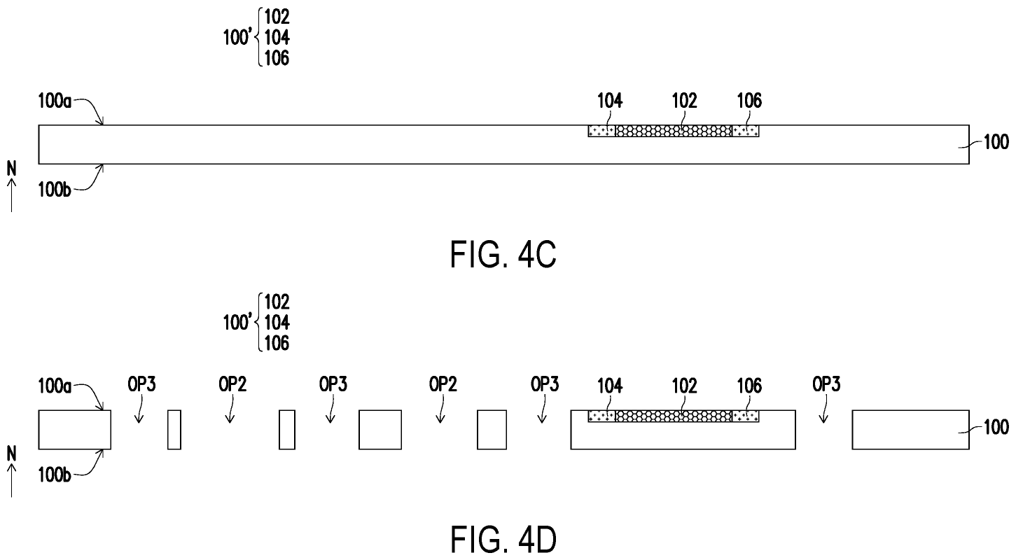

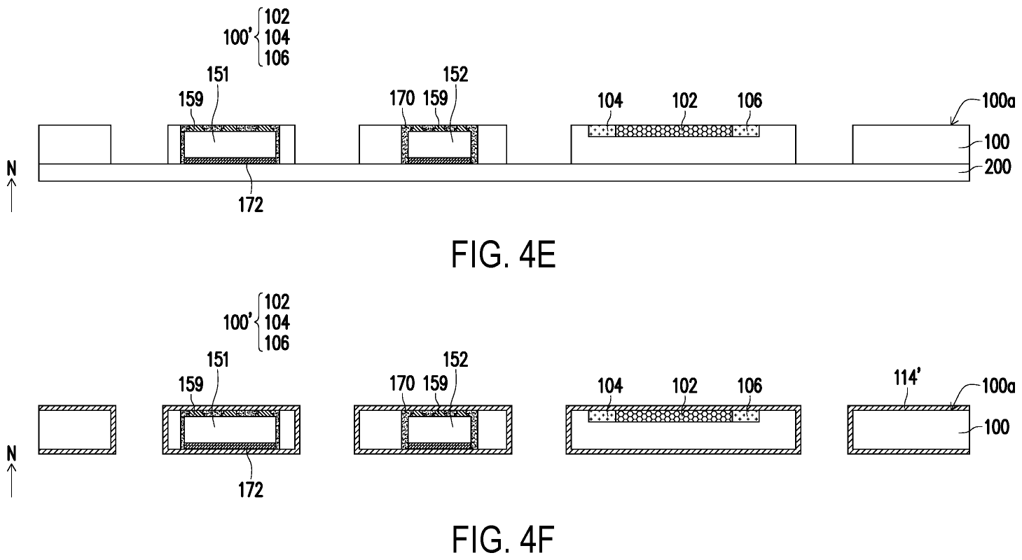

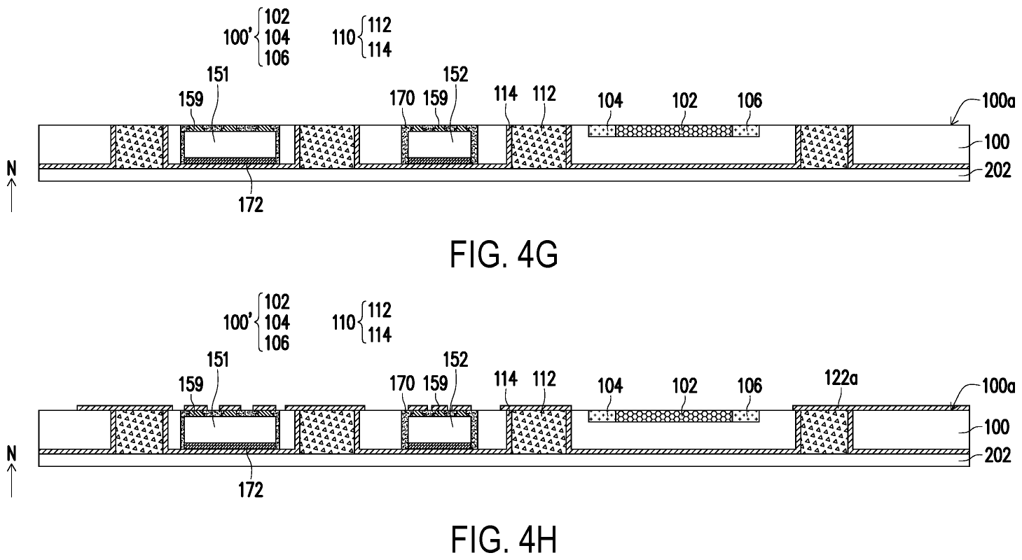

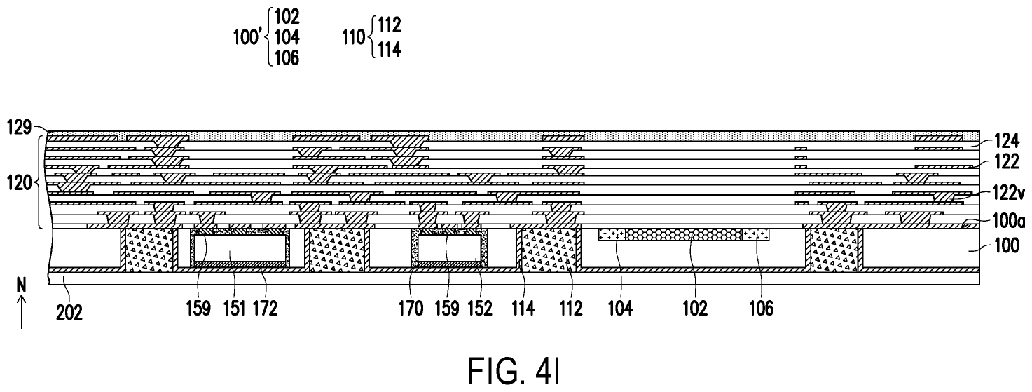

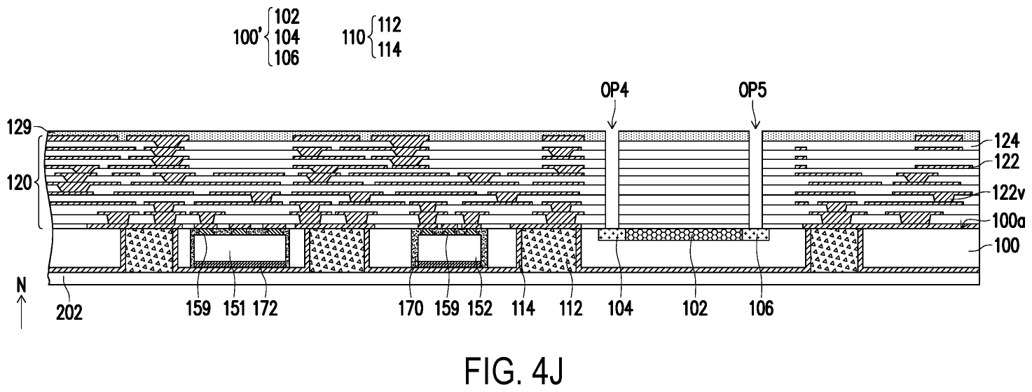

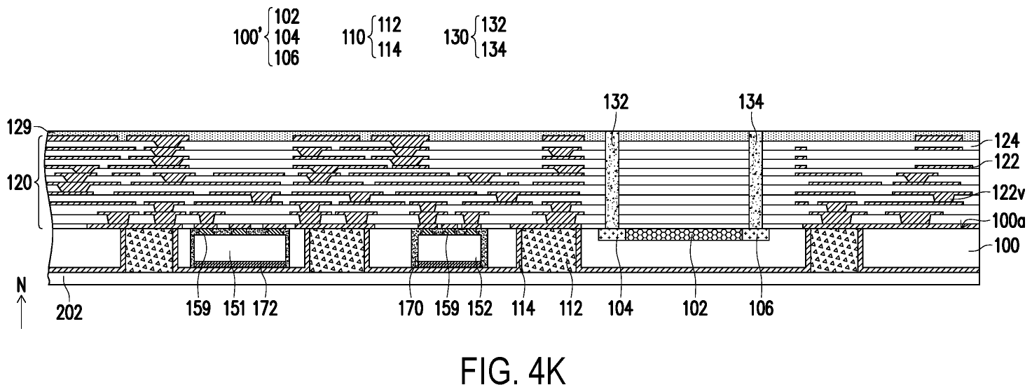

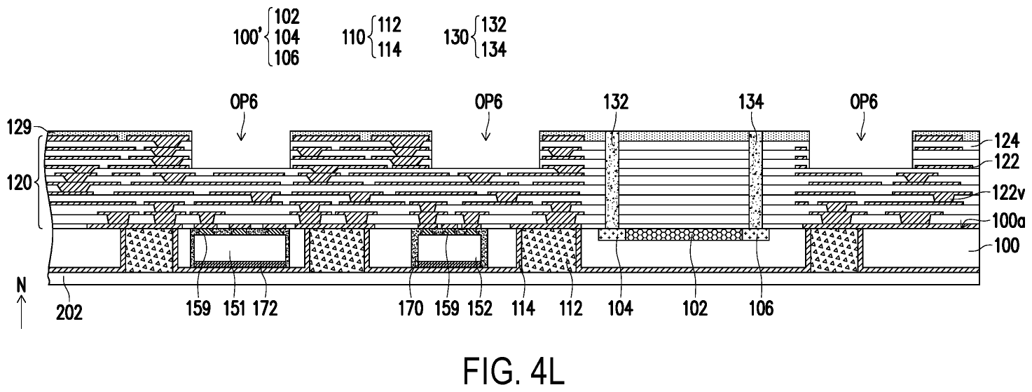

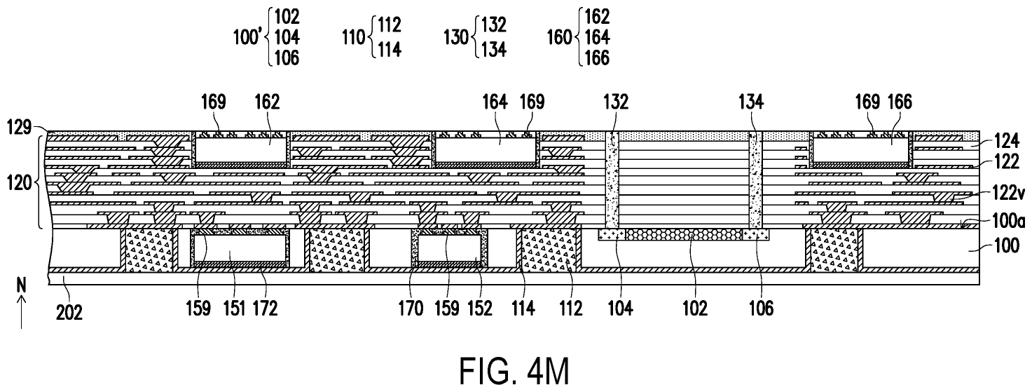

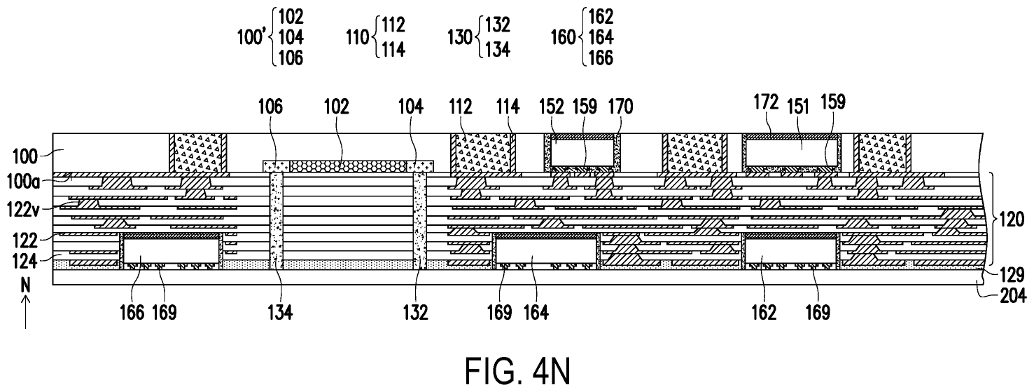

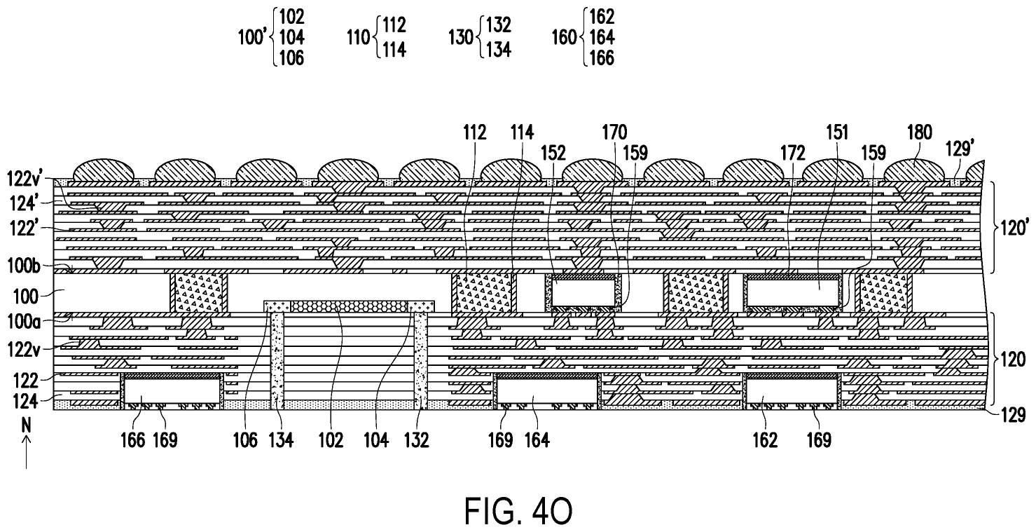

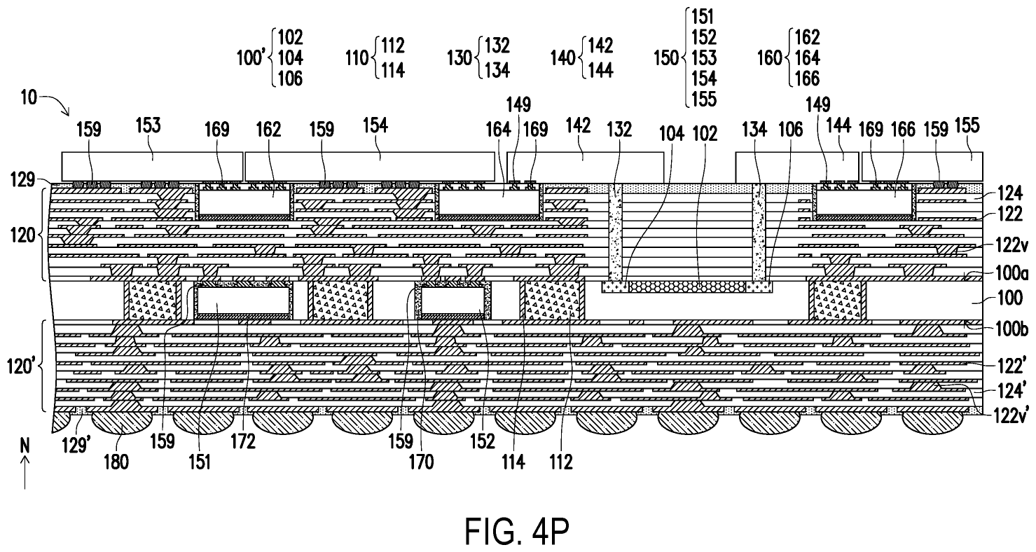

FIG. 4A through FIG. 4P are schematic sectional views at various stages in a method of fabricating a package structure 10 in accordance with some embodiments of the present disclosure. It should be noted herein that, in embodiment provided in FIGS. 4A to 4P, element numerals and partial content of the embodiments provided in FIG. 1 are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 4A, a mask layer 210 is formed on a glass substrate 100. The mask layer may be formed on both the first surface 100a and the second surface 100b of the glass substrate 100. In some embodiments, the mask layer 210 may be formed of a material substantially not diffused into the glass substrate 100. For example, the mask layer 210 may be a metal mask. The metal mask may include aluminum, titanium, an alloy thereof, a combination thereof, or other suitable material. The mask layer may be formed by deposition (such as chemical vapor deposition (CVD), physical vapor deposition (PVD), atomic layer deposition (ALD) or the like), electroplating, electroless plating, other suitable processes, and/or combinations thereof.

Then, the mask layer 210 is patterned to form an opening OP1 to expose a portion of the first surface 100a of the glass substrate 100. The opening OP1 may be formed by photolithography and/or etching process, such as by forming and patterning a photoresist (not shown) on the mask layer and then performing an etching process to remove a portion of the mask layer 210 exposed by the patterned photoresist to form the opening OP1. FIG. 4A has been simplified for the sake of clarity to better understand the inventive concepts of the present disclosure, and it is appreciated that the pattern of the opening OP1 should be corresponding to the pattern of the optical waveguide 102 and the grating couplers 104 and 106 subsequently formed.

Referring to FIG. 4B, an ion exchange process is performed on the glass substrate 100 to form a photonic component 100′ in the glass substrate 100. The photonic component 100′ includes an optical waveguide 102 and the grating couplers 104 and 106. For example, the glass substrate 100 with the patterned mask layer 210 may be immersed into a molten salt, such that an ion of the molten salt may be exchanged with an ion in the glass substrate 100 exposed by the opening OP1 through thermal diffusion, and thereby forming the optical waveguide 102 and the grating couplers 104 and 106 close to the first surface 100a of the glass substrate 100. The molten salt may include molten nitrates (such as LiNO₃, NaNO₃, KNO₃, RbNO₃, CsNO₃, AgNO₃, TlNO₃ or the like) or other suitable molten salts which may include ions selected from a group of Li⁺, Na⁺, K⁺, Rb⁺, Cs⁺, Ag⁺ and Tl⁺.

FIGS. 4A and 4B schematically illustrates one photonic component 100′ formed in the glass substrate, but this is no limited thereto. The amount and position of the photonic component 100′ formed in the glass substrate 100 may be adjusted based on the actual demands. For example, another photonic component 100″ (as shown in FIG. 3) may be formed close to the second surface 100b of the glass substrate 100 by similar process to the forming of the photonic component 100′.

Referring to FIG. 4C, the mask layer 210 is then removed by, for example, etching process (including wet etching, dry etching or the like) or other suitable process. Referring to FIG. 4D, a plurality of openings (such as openings OP2 and OP3) are formed. The openings OP2 and OP3 penetrate through the glass substrate 100. The openings OP2 and OP3 may be formed by punching process, laser drilling process or other suitable process.

Referring to FIG. 4E, the glass substrate 100 is disposed on a temporary carrier 200. The temporary carrier 200 may be a semiconductor carrier, a glass carrier, a ceramic carrier or other suitable carrier which can provide support for the glass substrate 100. The disclosure is not limited thereto. In some embodiments, the glass substrate 100 is attached to the temporary carrier 200 using, for example, a release layer (not shown), so that the temporary carrier 200 may be easily removed in the subsequent process.

Referring to FIG. 4E, the chips 151 and 152 are placed in the opening OP2. In some embodiments, the size of the opening OP2 (for example, a width of the opening OP2) is larger than the size of the corresponding chip (for example, a width of the chip 151 or the chip 152). In some embodiments, the chips 151 and 152 are attached to the temporary carrier 200 by an adhesive layer 172 to fix the chips 151 and 152 on the temporary carrier 200. In some embodiments, an insulating filling material 170 is filled in the opening OP2 to fix the chips 151 and 152 in the opening OP2, and thus the insulating filling material 170 is disposed between the chip 151 or the chip 152 and the glass substrate 100. The insulating filling material 170 may include epoxy resin, phenol resin or other suitable insulating material. In some embodiments, the insulating filling material 170 may further include fillers (such as silica or the like) to optimize the thermal expansion coefficient of the insulating filling material 170.

Referring to FIG. 4F, the temporary carrier 200 is peeled off from the glass substrate 100. Then, a conductive material layer 114′ is formed on the glass substrate 100 and sidewalls of the opening OP3. The conductive material layer 114′ may be formed by deposition (such as CVD, PVD, ALD or the like), electroplating, electroless plating, other suitable processes, and/or combinations thereof. In some embodiments, the conductive material layer 114′ includes metal or metal alloys, for example, tungsten (W), cobalt (Co), copper (Cu), aluminum (Al), nickel (Ni), ruthenium (Ru), gold (Au), silver (Ag), molybdenum (Mo), manganese (Mg), zirconium (Zr), alloys of the aforementioned metal, a combination thereof, or other suitable materials.

Referring to FIG. 4G, the glass substrate 100 is disposed on a temporary carrier 202, where the second surface 100b of the glass substrate 100 faces the temporary carrier 202. The temporary carrier 202 may be similar to the temporary carrier 200. In some embodiments, the second surface 100b of the glass substrate 100 is attached to the temporary carrier 202 using, for example, a release layer (not shown), so that the temporary carrier 202 may be easily removed in the subsequent process.

Then, an insulating pillar 112 is formed in the opening OP3. For example, an insulating material is filled in the opening OP3 and may be formed on the glass substrate 100. In some embodiments, a planarization process (such as chemical mechanical polishing (CMP), grinding process or other suitable process) is performed to remove excess insulating material formed on the glass substrate 100. In some embodiments, a portion of the conductive material layer 114′ formed on the first surface 100a of the glass substrate 100 is also removed by the planarization process to expose the first surface 100a of the glass substrate 100 and the chips 151 and 152, so that a top surface of the optical waveguide 102 may substantially level with a top surface of the insulating pillar 112. The portion of the conductive material layer 114′ formed on the sidewalls of the opening OP3 may be referred to the conductive layer 114, and the conductive layer 114 and the insulating pillar 112 together form a through-substrate-via 110.

In other embodiments, the conductive material layer 114′ may fill up the opening OP3 and form a conductive pillar as shown in FIG. 2. Therefore, the insulating material may not be formed in the opening OP3. In such an embodiment, the temporary carrier 200 may not be removed before or during the formation of the conductive pillar. That is the temporary carrier 200 in FIG. 4E may be used as the temporary carrier 202 in FIG. 4G.

Referring to FIGS. 4H and 41, a redistribution structure 120 including redistribution layers 122, conductive vias 122v and dielectric layers 124 is formed on the first surface 100a of the glass substrate 100. For example, In FIG. 4H, a first redistribution layer 122a is formed on the first surface 100a of the glass substrate 100. The first redistribution layer 122a may refer to the bottommost redistribution layer of the redistribution layers 122 of the redistribution structure 120. Specifically, a conductive material layer (not shown) may be formed on the first surface 100a of the glass substrate 100 and then patterned to form the first redistribution layer 122a. In some embodiments, the conductive material layer may be formed by, for example, CVD, PVD, ALD, sputtering, electrochemical plating, electroless plating, some other deposition process, or a combination of the foregoing. In some embodiments, a process for patterning the conductive material layer includes forming a mask layer (e.g., positive/negative photoresist, a hardmask, and etc.) on the conductive material layer, and performing an etching process (e.g., wet etching process, dry etching process, reactive ion etching (RIE) process, etc.) to the conductive material to remove the unmasked portion of the conductive material layer, and stripping away the mask layer. In some embodiments, the first redistribution layer 122a covers top surfaces of the insulating pillar 112 and the conductive layer 114, so that the first conductive layer 122a is electrically connected with the conductive layer 114. In some embodiments, the first redistribution layer 122a further extends on the first surface 100a of the glass substrate 100. In some embodiments, the first redistribution layer 122a is electrically connected with the chips 151 and 152.

In FIG. 4I, a dielectric material layer may be formed on the first redistribution layer 122a by, for example, chemical vapor deposition (CVD), physical vapor deposition (PVD), atomic layer deposition (ALD), spin-coating, some other deposition process, or a combination of the foregoing. Then, the dielectric material layer may be patterned via a lithography process, such as photolithography, extreme ultraviolet lithography, or the like to form a dielectric layer 124. The dielectric layer 124 may have corresponding openings for subsequent connection purpose. Then, a conductive material layer (not shown) may be formed on the dielectric layer 124 and in the openings and then patterned to form a redistribution layer 122 and a conductive via 122v. In some embodiments, the conductive material layer may be formed by, for example, CVD, PVD, ALD, sputtering, electrochemical plating, electroless plating, some other deposition process, or a combination of the foregoing. In some embodiments, a process for patterning the conductive material layer includes forming a mask layer (e.g., positive/negative photoresist, a hardmask, and etc.) on the metal material, and performing an etching process (e.g., wet etching process, dry etching process, reactive ion etching (RIE) process, etc.) to the conductive material layer to remove the unmasked portion of the conductive material, and stripping away the mask layer. The redistribution structure 120 may be formed by repeating the aforementioned process until the target number of the redistribution layers 122 is reached. In some embodiments, the dielectric layer 124 may include an oxide, such as silicon oxide or silicon oxynitride; a nitride, silicon nitride or silicon carbon nitride; a polymer-based dielectric material, such as polyimide, epoxy resin, acrylic resin, phenol resin, benzocyclobutene (BCB), polybenzooxazole (PBO), and/or any other suitable polymer-based dielectric material. The first redistribution layer 122a, the redistribution layer 122 and the conductive via 122v may be or include, for example, tungsten (W), cobalt (Co), copper (Cu), aluminum (Al), nickel (Ni), ruthenium (Ru), gold (Au), silver (Ag), molybdenum (Mo), manganese (Mg), zirconium (Zr), alloys of the aforementioned metal, a combination thereof, or other suitable conductive materials.

Subsequently, a passivation layer 129 is formed on the redistribution structure 120 by, for example, chemical vapor deposition (CVD), physical vapor deposition (PVD), atomic layer deposition (ALD), spin-coating, some other deposition process, or a combination of the foregoing. The passivation layer 129 may cover the topmost redistribution layer 122 of the redistribution structure 120. In some embodiments, a material of the passivation layer 129 includes silicon oxide, silicon nitride, silicon oxynitride, silicon carbide, silicon carbonitride, or other suitable insulating materials.

Referring to FIGS. 4J and 4K, an optical conductive via 130 (such as the first optical conductive via 132 or the second optical conductive via 134) is formed in the redistribution structure 120 to optically connect with the optical waveguide 102. For example, in FIG. 4J, an opening OP4 and an opening OP5 penetrating through the redistribution structure 120 and the passivation layer 129 to expose a portion of the photonic component 100′ are formed. The opening OP4 and an opening OP5 may be formed by photolithography and/or etching process, such as by forming and patterning a photoresist (not shown) on the passivation layer 129 and then performing an etching process to remove a portion of the passivation layer 129 and dielectric layers 124 exposed by the patterned photoresist to form the openings OP4 and OP5. In some embodiments, the opening OP4 and an opening OP5 penetrate through the stacked dielectric layers 124 of the redistribution structure 120, but not penetrate through the conducive layer 122 of the redistribution structure 120. In some embodiments, the opening OP4 exposes a portion of the grating coupler 104 and the opening OP5 exposes a portion of the grating coupler 106.

In FIG. 4K, a light-transmitting material is filled in the openings OP4 and OP5 to form the first optical conductive via 132 and the second optical conductive via 134. In some embodiments, the light-transmitting material includes a polymer material and nano-fillers distributed in the polymer material.

Referring to FIG. 4L, openings OP6 are formed in the redistribution structure 120 by photolithography and/or etching process, similar to the forming of the openings OP4 and OP5 described in FIG. 4J. A size of the opening OP6 (for example, a width of the opening OP6) is larger than a size of the corresponding bridge chip 160 (for example, a width of the bridge chip 160). In some embodiments, the opening OP6 penetrates the passivation layer 129 and a portion of the stacked dielectric layers 124 of the redistribution structure 120, but does not penetrate through the redistribution layers 122 of the redistribution structure 120.

Referring to FIG. 4M, bridge chips 160 (such as bridge chips 162, 164 and 166) are placed in the corresponding openings OP6. In some embodiments, a bottom surface of the bridge chip 160 is attached to a bottom of the opening OP6 by an adhesive layer 172. The insulating filling material 170 is then filled in the openings OP6 to fix the bridge chips 160 in the openings OP6. The insulating filling material may be located between the bridge chips 160 and the redistribution structure 120. In some embodiments, top surfaces of the conductive connectors 169 of the bridge chips 160 substantially level with a top surface of the passivation layer 129.

Although the embodiment shows that the bridge chips 160 are disposed in the redistribution structure 120 after the forming of the optical conductive via 130, the disclosure is not limited thereto. The order of the manufacturing steps may be changed based on the demand. In other embodiments, the bridge chips 160 may be disposed in the redistribution structure 120 before the forming of the optical conductive via 130.

Referring to FIG. 4N, the structure in FIG. 4M is flipped over and attached to a temporary carrier 204 using, for example, a release layer (not shown). The temporary carrier 204 may be similar to the temporary carrier 200 or 202. Then, the temporary carrier 202 is peeled off from the structure, and thus the second surface 100b of the glass substrate 100 is exposed. A planarization process (such as chemical mechanical polishing (CMP), grinding process or other suitable process) is performed to remove a portion of the conductive material layer 114′ formed on the second surface 100b of the glass substrate 100 and expose the second surface 100b of the glass substrate 100.

Referring to FIG. 4O, a redistribution structure 120′ including the redistribution layers 122′, conductive vias 122v′ and dielectric layers 124′ is formed on the second surface 100b of the glass substrate 100. The forming and the materials of the redistribution structure 120′ is similar to the redistribution structure 120 described in FIGS. 4H and 41. Then, a passivation layer 129′ is formed on the redistribution structure 120′. The forming and the material of the passivation layer 129′ is similar to the passivation layer 129 described in FIG. 4I.

In an embodiment where a photonic component 100″ is formed close to the second surface 100b of the glass substrate 100 as shown in FIG. 3, a third optical conductive via 132′ and a fourth optical conductive via 134′ are formed in the redistribution structure 120′. The forming and the materials of the third optical conductive via 132′ and the fourth optical conductive via 134′ is similar to that of the first optical conductive via 132 and the second optical conductive via 134 described in FIGS. 4J and 4K.

Continued on FIG. 4O, a plurality of conductive terminals 180 are formed on the passivation layer 129′ and electrically connected with the redistribution structure 120′. For example, openings (not shown) are first formed in the passivation layer 129′ to expose a portion of the redistribution layer 122′ of the redistribution structure 120′ and then the conductive terminals 180 may be formed in the openings by ball placement process, reflow process or other suitable process. In some embodiments, under-ball metallurgy (UBM) layers (not shown) may be formed in the openings before the conductive terminals are formed to enhance the adhesion strength between the conductive terminals 180 and the passivation layer 129′. The numbers of the conductive terminals 180 is not limited to the drawings of the embodiments, and may be selected and designated based on the demand and design requirements.

In some embodiments, additional chips or photonic chips may be disposed on the passivation layer 129′ to electrically connected with the redistribution structure 120′. For example, in an embodiment where a photonic component 100″ is formed close to the second surface 100b of the glass substrate 100 as shown in FIG. 3, a third photonic chip 142′ and a fourth photonic chip 144′ may be disposed on the passivation layer 129′ and optically connected with the photonic component 100″ by the third optical conductive via 132′ or the fourth optical conductive via 134′.

Referring to FIG. 4P, the structure in FIG. 4O is flipped over and the temporary carrier 204 is peeled off from the structure, so that the passivation layer 129 is exposed. The chips 153-155, a first photonic chip 142 and a second photonic chip 144 are disposed on the passivation layer 129 and electrically connected to the redistribution structure 120 and/or the bridge chip 160. For example, the passivation layer 129 is patterned to form a plurality of openings (not show) to expose a portion of the redistribution layer 122 for subsequent connection purpose. Then, a portion of the conductive connectors 159 of the chips 153-155 are disposed in the openings of the passivation layer 129 to electrically connect the chips 153-155 and the redistribution structure 120, and another portion of the conductive connectors 159 of the chips 153-155 are physically and electrically connected with the conductive connectors 169 of the bridge chip 160. In FIG. 4P, the chip 153 is physically and electrically connected with the redistribution structure 120 and the bridge chip 162. The chip 154 is physically and electrically connected with the redistribution structure 120 and/or the bridge chips 162 and 164. The chip 155 is physically and electrically connected with the redistribution structure 120 and the bridge chip 166.

A portion of the first photonic chip 142 (such as the electronic die of the first photonic chip 142) may be electrically connected with the bridge chip 164 through the corresponding conductive connectors 169 of the bridge chip 164 and the conductive connectors 149 of the first photonic chip 142, and another portion of the first photonic chip 142 (such as the photonic die of the first photonic chip 142) may be optically connected with the first optical conductive via 132. A portion of the second photonic chip 144 (such as the electronic die of the second photonic chip 144) may be electrically connected with the bridge chip 166 through the corresponding conductive connectors 169 of the bridge chip 166 and the conductive connectors 149 of the second photonic chip 144, and another portion of the second photonic chip 144 (such as the photonic die of the second photonic chip 144) may be optically connected with the second optical conductive via 134.

In some embodiments, the first photonic chip 142 is in direct contact with the first optical conductive via 132, and the second photonic chip 144 is in direct contact with the second optical conductive via 134, so that there is no gap between the first photonic chip 142 and the first optical conductive via 132, and between the second photonic chip 144 and the second optical conductive via 134. In some embodiments, the first photonic chip 142 and the second photonic chip 144 are in direct contact with the passivation layer 129.

In some embodiments, an underfill (not shown) is optionally formed between the gap of the chips 153-155 and the passivation layer 129 to at least laterally cover the conductive connectors 159. The underfill may include, for example, a polymer, epoxy resin, molding underfill, or the like. In some embodiments, the underfill may be formed by underfill dispensing, a capillary flow process, or any other suitable method.

Although the embodiment shows that the chips 153-155, a first photonic chip 142 and a second photonic chip 144 are disposed on the passivation layer 129 after the forming of the redistribution structure 120′, the disclosure is not limited thereto. The order of the manufacturing steps may be changed based on the demand. In other embodiments, the chips 153-155, a first photonic chip 142 and a second photonic chip 144 are disposed on the passivation layer 129 before the forming of the redistribution structure 120′ and after the bridge chips 160 are disposed in the redistribution structure 120.

Embodiments may achieve advantages. For example, a portion of the glass substrate in the package structure may be used as the optical waveguide to transmit optical signal to reduce power consumption and increase bandwidth density. The occurrence of warpage may be reduced due to improved CTE matching between the glass substrate and the chip and thereby it is suitable for large area application.

In accordance with some embodiments, a package structure is described. The package structure includes a glass substrate, a through-substrate-via and a redistribution structure. The glass substrate includes a first optical waveguide. The through-substrate-via penetrates through the glass substrate. The redistribution structure is disposed on the glass substrate and electrically connected to the through-substrate-via.

In accordance with another embodiment of the disclosure, a package structure is described. The package structure includes a glass substrate, a redistribution structure, a first photonic chip, a first optical conductive via and a through-substrate-via. The glass substrate includes a first region and a second region. A refraction index of the first region is larger than a refraction index of the second region. The redistribution structure is disposed on the glass substrate. The first photonic chip is disposed on the redistribution structure. The first optical conductive via penetrates through the redistribution structure to optically connect between the first region and the first photonic chip. The through-substrate-via penetrates through the glass substrate in the second region and electrically connected with a redistribution layer of the redistribution structure.

In accordance with yet another embodiment of the disclosure, a manufacturing method of forming a package structure is described. The manufacturing method at least includes the following steps. An ion exchange process is performed on a portion of a glass substrate to form a photonic component in the glass substrate, wherein the photonic component includes an optical waveguide. A through-substrate-via is formed in the glass substrate. A redistribution structure is formed on the glass substrate. An optical conductive via is formed in the redistribution structure to optically connect with the optical waveguide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a glass substrate comprising a first optical waveguide;
a through-substrate-via penetrating through the glass substrate; and
a redistribution structure disposed on the glass substrate and electrically connected to the through-substrate-via.

2. The package structure according to claim 1, wherein the through-substrate-via comprises:
an insulating pillar embedded in the glass substrate; and
a conductive layer surrounding the insulating pillar, wherein the insulating pillar is spaced apart from the glass substrate by the conductive layer.

3. The package structure according to claim 1, wherein the through-substrate-via comprises a conductive pillar in contact with the glass substrate.

4. The package structure according to claim 1, wherein the first optical waveguide comprises ions selected from a group of Li⁺, Na⁺, K⁺, Rb⁺, Cs⁺, Ag⁺ and Tl⁺.

5. The package structure according to claim 4, wherein an ion concentration of the ions in the first optical waveguide is larger than an ion concentration of the ions in the glass substrate.

6. The package structure according to claim 1, wherein the first optical waveguide is located close to a first surface of the glass substrate.

7. The package structure according to claim 6, further comprising a second optical waveguide located close to a second surface of the glass substrate, wherein the second surface is opposite to the first surface.

8. The package structure according to claim 1, further comprising:
an optical conductive via penetrating through the redistribution structure to optically connect with the first optical waveguide.

9. The package structure according to claim 8, wherein a refraction index of the optical conductive via is substantially equal to a refraction index of the first optical waveguide.

10. The package structure according to claim 1, further comprising:
a chip embedded in the glass substrate and electrically connected with the redistribution structure, wherein a surface of the optical waveguide substantially levels with a surface of the chip.

11. A package structure, comprising:
a glass substrate comprising a first region and a second region, wherein a refraction index of the first region is larger than a refraction index of the second region;
a redistribution structure disposed on the glass substrate;
a first photonic chip disposed on the redistribution structure;
a first optical conductive via penetrating through the redistribution structure to optically connect between the first region and the first photonic chip; and
a through-substrate-via penetrating through the glass substrate in the second region and electrically connected with a redistribution layer of the redistribution structure.

12. The package structure according to claim 11, wherein the optical conductive via comprises a polymer material and nano-fillers distributed in the polymer material.

13. The package structure according to claim 11, further comprising:
a second photonic chip disposed on the redistribution structure; and
a second optical conductive via penetrating through the redistribution structure to optically connect between the first region and the second photonic chip, wherein the first optical conductive via, the second optical conductive via and the first region of the glass substrate form an optical path to transfer an optical signal between the first photonic chip and the second photonic chip.

14. The package structure according to claim 13, wherein the first photonic chip and the second photonic chip each comprises an electronic die and a photonic die bonded to each other, and the photonic die faces the redistribution structure.

15. The package structure according to claim 13, wherein a refraction index of the first optical conductive via, a refraction index of the second optical conductive via and the refraction index of the first region of the glass substrate are substantially identical.

16. The package structure according to claim 11, wherein the first region comprises an optical waveguide and a grating coupler optically coupled between the waveguide and the first optical conductive via.

17. A manufacturing method of forming a package structure, comprising:
performing an ion exchange process on a portion of a glass substrate to form a photonic component in the glass substrate, wherein the photonic component includes an optical waveguide;
forming a through-substrate-via in the glass substrate;
forming a redistribution structure on the glass substrate; and
forming an optical conductive via in the redistribution structure to optically connect with the optical waveguide.

18. The manufacturing method according to claim 17, wherein forming the through-substrate-via in the glass substrate comprises:
forming an opening penetrating through the glass substrate; and
depositing a conductive layer in the opening.

19. The manufacturing method according to claim 18, wherein forming the through-substrate-via in the glass substrate further comprises:
filling an insulating material in the opening, wherein the conductive layer is between the insulating material and the glass substrate.

20. The manufacturing method according to claim 17, wherein forming the optical conductive via in the redistribution structure comprises:
forming an opening penetrating through the redistribution structure to expose a portion of the photonic component; and
filling a light-transmitting material in the opening, wherein the light-transmitting material comprises a polymer material and nano-fillers distributed in the polymer material.
